(19) United States
(12) Patent Application Publication
(10) Pub. No.: US 2015/0187945 A1
(43) Pub. Date: Jul. 2, 2015

(54) SALICIDE PROTECTION DURING CONTACT METALLIZATION AND RESULTING SEMICONDUCTOR STRUCTURES

(71) Applicant: GLOBALFOUNDRIES Inc., Grand Cayman (KY)

(72) Inventors: Vimal K. Kamineni, Albany, NY (US); Ruilong Xie, Schenectady, NY (US); Robert Miller, Yorktown Heights, NY (US)

(73) Assignee: GLOBALFOUNDRIES Inc., Grand Cayman (KY)

(21) Appl. No.: 14/146,430

(22) Filed: Jan. 2, 2014

(51) Int. Cl. H01L 29/78; H01L 29/45; H01L 21/283; H01L 29/417; H01L 21/3213; H01L 21/311; H01L 29/66; H01L 29/49

(52) U.S. Cl. CPC H01L 29/7851; H01L 29/66795; H01L 29/45; H01L 29/495; H01L 29/41791; H01L 21/32133; H01L 21/31111; H01L 21/283; H01L 29/6656

(57) ABSTRACT

A semiconductor transistor has a structure including a semiconductor substrate, a source region, a drain region and a channel region in between the source region and the drain region. A gate is provided above the channel region. A silicon nitride protective layer is provided over the source region and the drain region, along with a silicon nitride cap over the gate region. The silicon nitride protective layer is configured to allow punch-through of the protective layer after source and drain openings are created, while preventing etching through the cap above the gate. The self-aligned source, drain and gate contacts are formed while protecting the source and drain salicide using the silicon nitride protective layer and gate cap.

### BACKGROUND OF THE INVENTION

1. Technical Field

The present invention generally relates to semiconductor devices and methods of fabricating semiconductor devices. More particularly, the present invention relates to preventing damage to salicide in transistor fabrication during self-aligned contact metallization.

2. Background Information

Salicide processes have been widely used to form salicide contacts on gate regions and source/drain regions during semiconductor device fabrication to improve the performance of the semiconductor device. As one skilled in the art will know, salicide is simply “self-aligned silicide.” The salicide layer improves the operational speed of the semiconductor device by reducing the contact resistance between the metal contact and the source, drain and gate regions.

Semiconductor fabrication often includes one or more etching processes performed using a photoresist mask, to form contacts over salicide in source, drain and gate regions of a semiconductor transistor. The photoresist mask is subsequently removed by employing dry chemistries involving reactive oxygen, such as oxygen plasma. The use of oxygen plasma results in the formation of polymeric etch residues at the bottom of contact openings in source, drain and gate regions of the semiconductor device. After the oxygen plasma ash is performed, the polymeric etch residues are removed by employing prior art processes. However, the oxygen plasma ash processes and other prior art processes cause damage to the exposed salicide and increase its resistance, resulting in degradation of the performance of the semiconductor device. In the most advanced applications of semiconductor fabrication, there is a need for the contact metallization to the source and drain to be self-aligned with respect to the gate structure, as a means to increase the number of devices in a given semiconductor area. Process requirements for achieving self-aligned contacts further limit the available processing alternatives to avoid salicide damage.

Hence, there exists a need to prevent damage to salicide during subsequent processes and improve the performance of semiconductor device.

### SUMMARY OF THE INVENTION

The shortcomings of the prior art are overcome and additional advantages are provided through the provision, in one aspect, of a method of preventing damage to salicide during contact metallization. The method includes providing a semiconductor structure for a transistor, the structure including a semiconductor substrate, a source region, a drain region and a channel region therebetween. The structure further includes a layer of protective material above the source region and the drain region, a gate coupled to the channel region and having a cap and spacers, the cap and spacers including a protective material, and a layer of dielectric material enclosing the cap, spacers and protective layer above the source and drain regions. The method further includes etching openings to the gate cap and the protective layer over the source and drain regions, etching through the protective layer to expose the source and drain regions without etching through the gate cap, creating silicide in the source region and the drain region, creating contacts in the source and drain openings, extending the gate opening through the gate cap to expose the gate, and creating a contact in the gate opening.

In accordance with another aspect, a transistor is provided, including a semiconductor substrate, a source region, a drain region, a channel region therebetween, and a metal gate coupled to the channel region, at least a top conductive portion of the metal gate including tungsten. The transistor further includes an opening through at least one layer of one or more materials to each of the source region, drain region and gate, and a gate contact including tungsten filling the gate opening, the gate contact being in direct contact with the top conductive portion of the gate. The transistor further includes silicide for the source and drain regions, a liner lining inner surfaces of the source and drain openings part way up inner walls thereof, and self-aligned tungsten contacts filling the source and drain openings.

In accordance with another aspect, a semiconductor structure is provided, including a semiconductor substrate; a source region, a drain region and a channel region therebetween; a layer of protective material above the source region and the drain region; a gate coupled to the channel region and having a cap and spacers, the cap and spacers comprising a protective material; a layer of dielectric material enclosing the cap and source and drain regions; and wherein the structure includes intermediate openings down to the gate cap and the protective layer over the source and drain regions.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a plan-view of a semiconductor structure 100, obtained at an end stage of semiconductor fabrication of transistors, in accordance with one or more aspects of the present invention.

FIG. 2 is a cross-sectional elevational view of one example of the semiconductor structure of FIG. 1, which includes a gate structure, a source region and a drain region, in accordance with one or more aspects of the present invention.

FIG. 3 depicts one example of the structure of FIG. 2 after providing a lithographic stack over the semiconductor structure, in accordance with one or more aspects of the present invention.

FIG. 4 depicts one example of the structure of FIG. 3 after patterned openings have been created in the lithographic stack over the source region and the drain region, in accordance with one or more aspects of the present invention.

FIG. 5 depicts one example of the structure of FIG. 4 after patterning and creating an intermediate source opening and drain opening, in accordance with one or more aspects of the present invention.

FIG. 6 depicts one example of the structure of FIG. 5 after punching through a protective layer above the source and drain to create a source opening and a drain opening, in accordance with one or more aspects of the present invention.

FIG. 7 depicts one example of the structure of FIG. 6 after creating salicide in the source opening and the drain opening, in accordance with one or more aspects of the present invention.

FIG. 8 depicts one example of the structure of FIG. 7 after creating tungsten contacts in the source opening and the drain opening, in accordance with one or more aspects of the present invention.

FIG. 9 depicts one example of the structure of FIG. 8 after creating a gate opening, in accordance with one or more aspects of the present invention.

FIG. 10 depicts one example of the resultant structure of FIG. 9 after creating a tungsten contact in the gate opening, in accordance with one or more aspects of the present invention.

FIG. 11 depicts one alternate example of the structure of FIG. 8 after partial recessing of the tungsten contacts in the source opening and the drain opening, in accordance with one or more aspects of the present invention.

FIG. 12 depicts one example of the structure of FIG. 11 after creating a gate opening, in accordance with one or more aspects of the present invention.

FIG. 13 is a plan-view of the resultant structure of FIG. 12 after creating a tungsten contact in the gate opening, in accordance with one or more aspects of the present invention.

FIG. 14 is a plan-view of the resultant structure of FIG. 12, after creating a tungsten contact in the source opening and the drain opening, in accordance with one or more aspects of the present invention.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

Reference is made below to the drawings, which are not drawn to scale for ease of understanding, wherein the same reference numbers are used throughout different figures to designate the same or similar components.

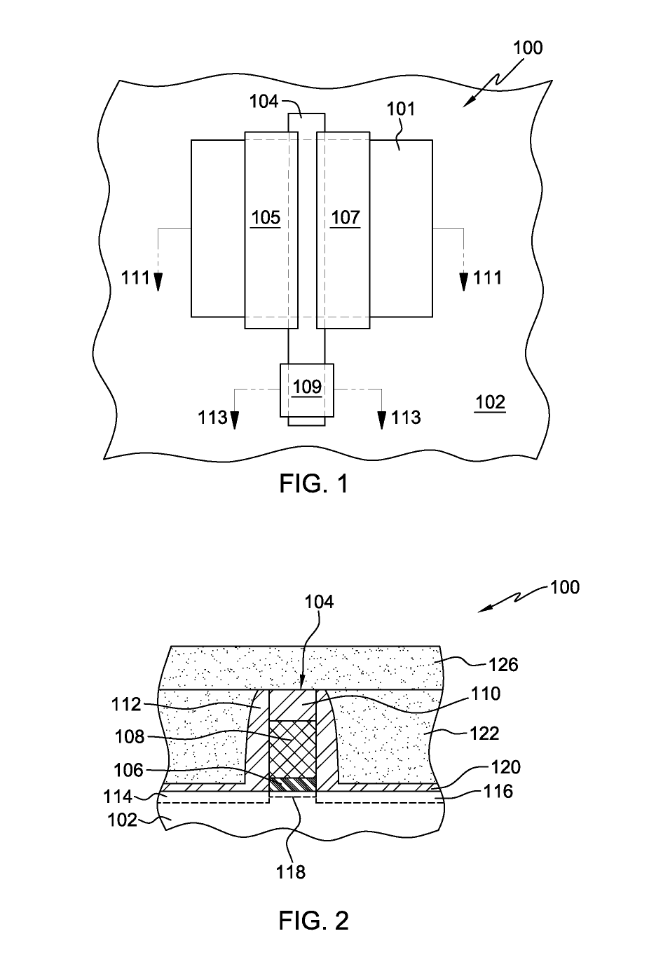

FIG. 1 is a plan view of a semiconductor structure 100, obtained at an end stage of semiconductor fabrication of transistors and illustrates semiconductor fin 101 over substrate 102, and gate structure 104 overlapping semiconductor fin 101. At the stage of fabrication in FIG. 1, structure 100 further includes a source contact 105, drain contact 107 and an offset gate contact 109. As described in more detail below, cross-section 111 represents a view taken along the source and the drain and looking toward the gate contact, while cross-section 113 represents a view taken along the gate and looking away from the source and drain contacts.

FIG. 2 is a cross-sectional view of one example of an intermediate stage of fabrication of semiconductor structure 100 of FIG. 1, prior to contact creation taken along the cross-section 111, the semiconductor structure, in this case, being a FinFET. At the stage of fabrication depicted in FIG. 2, the intermediate structure 100 includes a substrate 102, such as a bulk semiconductor material, for example, a bulk silicon wafer. As one skilled in the art will understand, where, as in the present example, a bulk semiconductor material is used, many transistors will be present, such that what is shown in FIG. 1 is repeated a large number of times across the wafer. In one example, substrate 102 may include any silicon-containing substrate including, but not limited to, silicon (Si), single crystal silicon, polycrystalline Si, amorphous Si, silicon-on-nothing (SON), silicon-on-insulator (SOI) or silicon-on-replacement insulator (SRI) or silicon germanium substrates and the like. Substrate 102 may in addition or instead include various isolations, dopings and/or device features. The substrate may include other suitable elementary semiconductors, such as, for example, germanium (Ge), a compound semiconductor, such as silicon carbide (SiC), gallium arsenide (GaAs), gallium phosphide (GaP), indium phosphide (InP), indium arsenide (InAs), and/or indium antimonide (InSb) or combinations thereof an alloy semiconductor including GaAsP, AlInAs, GaInAs, GaInP, or GaInAsP or combinations thereof. The substrate 102 may be a planar substrate, or three-dimensional, such as FINs or Nanowires.

Continuing with FIG. 2, gate structure 104 may be disposed over substrate 102. As one skilled in art will understand, gate structure 104 may be fabricated using a conventional “gate-first” process, or a conventional “gate-last process” (also referred to as replacement metal gate process). In one example, gate structure 104 may include a dielectric layer 106. In a specific example, dielectric layer 106 may include silicon dioxide (SiO₂) and may be thermally grown or deposited by a number of different processes, for example, a chemical vapor deposition (CVD) process. In another specific example, dielectric layer 106 may also include a high-k dielectric material with a dielectric constant greater than about, for instance, 3.9 (note that k=3.9 for SiO₂). Examples of high-k dielectric materials may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide and lead zinc niobate. A “dummy” gate material 108 may be deposited over dielectric layer 106 and may include, for example, amorphous-silicon (a-Si), polycrystalline silicon or silicided polycrystalline silicon. In another example, gate material 108 may also include a metal gate structure, which may typically include one or more conformally-deposited work function materials such as, for example, titanium nitride (TiN), titanium aluminide (TiAl) and tantalum nitride (TaN) and low resistance conducting metal such as, for example, tungsten (W), aluminum (Al) and cobalt (Co) disposed over the one or more conformally-deposited work function materials.

Continuing further with FIG. 2, a cap layer 110, which acts as a hard mask, is disposed over gate material 108. As is understood in the art, cap layer 110 is deposited to prevent short-circuiting, otherwise known as contact-to-gate (CTG) shorts, when the gate material comes into contact with the source/drain contact material, during subsequent fabrication. Cap layer 110 may include an insulator material such as, for example, silicon nitride, and may be deposited using any conventional deposition process, such as, for example, CVD, PVD and the like.

Referring still to FIG. 2, spacers 112 are situated along the sides of gate structure 104, including cap layer 110. Spacers 112 are film layers (or sidewall spacers) formed along the sidewalls of gate structure 104, and may be fabricated by depositing the film layers using conventional deposition processes, such as, for example, CVD, low-pressure CVD (LP-CVD), or plasma-enhanced CVD (PE-CVD), and subsequently etched using anisotropic etch processes to create spacers 112 along the sides of gate structure 104. Note that the spacers, having a conventional thickness, may include or be fabricated of a protective material, such as, for example, silicon nitride or preferably a low-k dielectric material with a dielectric constant less than, for instance, about 3.9 (note that k=3.9 for SiO₂). Examples of low-k dielectric material may include, but are not limited to, silicon oxynitride (SiON) and silicon boron carbonitride (SiBCN). In a specific example, silicon nitride may be deposited using a halogen-free precursor, such as, for example, bis(t-butylamino)silane (BTBAS) (SiC₈N₂H₂₂) and ammonia (NH₃) at about 550° C.

As is understood in the art and shown further in FIG. 2, a source region 114, a drain region 116 and a channel region 118 therebetween are associated with each gate, and provided over substrate 102. The source and drain regions may be formed using any suitable techniques, including, for example, ion implantation, epitaxial growth of the embedded source/drain materials and activation anneals. By way of example, source region 114, drain region 116 and channel region 118 may be part of a planar-type transistor or a FinFET situated across a top of a fin. It will be understood that the positioning of the source region and drain region may be interchanged.

A first layer of protective material 120 extends laterally over the source 114 and drain 116 regions adjacent to the gate structure 104. Although shown as contiguous with spacers 112, it will be understood that first layer 120 need not be the same material as the spacers. Note that the first layer of protective material may generally be any film of protective material (or a hard mask) which may function as an etch stop while being configured to allow punch-through for contact with the underlying source and drain regions, as described further below. As is understood in the art, the first layer of protective material also facilitates in protecting the underlying source region 114 and drain region 116 from ionic impurities, such as Na⁺, K⁺ diffusing into active region during subsequent chemical mechanical planarization (CMP) processes. Note that the first layer of protective material 120 may include a material, such as, for example, silicon nitride and may have a thickness, such as to allow punch-through, for instance, in the range of about 3 nanometers to about 20 nanometers. As used herein, the term “punch-through” refers to etching of the first layer of protective material to reach the source and drain regions for subsequent processing.

Continuing with FIG. 2, a layer of a dielectric filler material 122 is shown disposed over the first layer of protective material 120, encompassing the gate structure 104 and spacers 112. In one example, dielectric layer 122, having a conventional thickness, may be, for instance, a field oxide of relatively low quality within the spectrum of available oxides. In a specific example, the field oxide may include flowable oxide, such as, for example, hydrogen silsesquioxane polymer or a carbon free silsesquioxane polymer, which may be deposited by a flowable chemical vapor deposition (F-CVD). In another example, dielectric layer 122 may include, but is not limited to, stoichiometric or non-stoichiometric silicon nitride (SiN or Si₃N₄), silicon oxide (SiO₂), or fluorinated silicate glass (FSG). A chemical mechanical polish of dielectric layer 122, may be performed to expose an upper surface of gate structure 104.

An additional layer 126 of dielectric material may be disposed by conventional CVD deposition over dielectric filler material 122 and over gate structure 104 and spacers 112, as further shown in FIG. 2. Note that this additional dielectric layer advantageously facilitates subsequent patterning of the semiconductor structure to create contact openings, which in turn, facilitate formation of conductive contacts or contact metallization to electrically connect to the active regions of the transistor including, for instance, the source region, the drain region and the gate structure. Note that additional dielectric layer 126 may include, for example, a material that is substantially similar to the material of dielectric layer 122. In one example, the additional dielectric layer 126 may include silicon dioxide (SiO₂). In another example, additional dielectric layer 126 may include, but is not limited to, low-k oxide, flowable oxide (SiO₂), or fluorinated silicate glass (FSG).

As will be subsequently explained, fabrication of the semiconductor structure generally proceeds by patterning of the structure to create one or more electrically conductive contacts or contact metallization to electrically connect to the one or more gate structures, source regions and drain regions of the transistor(s). This contact metallization may be achieved by sequentially patterning the structure to create openings over the various active regions. In the present example, this patterning begins with the source region and the drain region.

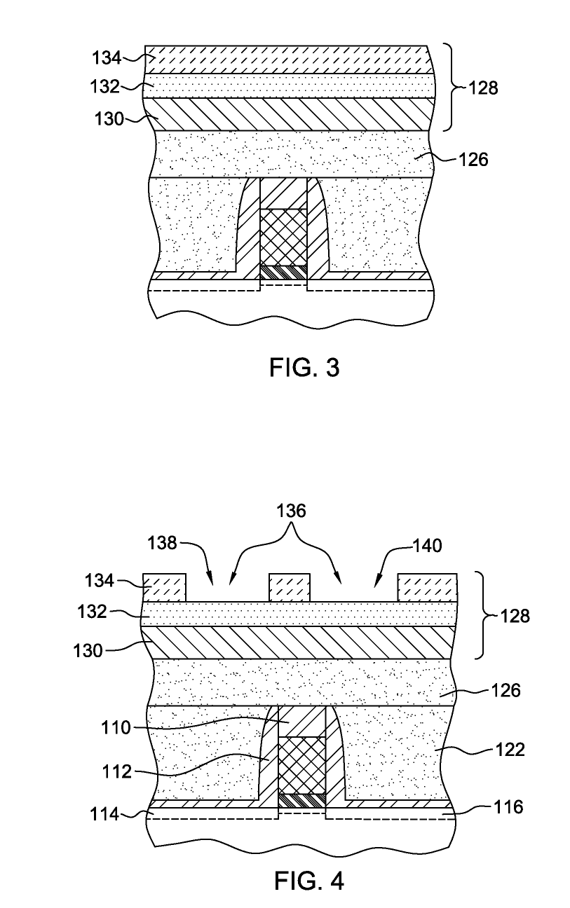

Accordingly, as depicted in FIG. 3, one or more lithographic processing steps may be performed to etch through the multilayer structure of FIG. 2, to create electrically conductive contacts or contact metallization to electrically connect to the source and drain regions, that are self-aligned to the gate structures, and thereby forming self-aligned contacts. These lithographic processing steps may include providing a lithographic stack 128 over additional dielectric layer 126, as depicted in FIG. 3. As discussed herein, the lithographic stack 128 may include an organic planarizing layer (OPL) 130, an anti-reflective coating material layer 132 and a layer of photoresist 134. The organic planarizing layer 130, which is used to transfer a pattern from the overlying photoresist layer 134 in subsequent lithography processing, may be formed using conventional spin-coating processes. In one example, organic planarizing layer 130 may be any of those conventionally employed during a pattern transfer process and may include an organic polymer, for example, polyacrylate resin, epoxy resin, phenol resin, polyamide resin, polyimide resin, unsaturated polyester resin, polyphenylenether resin, polyphenylenesulfide resin, or benzocyclobutene (BCB). The thickness of the organic planarizing layer may preferably be about 50 nanometers to about 200 nanometers.

Anti-reflective coating material layer 132, which may be, for example, a silicon anti-reflective layer (Si-ARC), is deposited over organic planarizing layer 130 to minimize any pattern distortion due to reflections. Anti-reflective coating material layer 132 may include materials having silicon and nitrogen, silicon and oxygen, or silicon, oxygen and nitrogen, or an organic polymer, or combinations thereof. The thickness of the anti-reflecting coating material layer 132 may preferably be about 20 nanometers to about 40 nanometers. As is known, a layer of light-sensitive material, such as, for example, photo resist layer 134, protecting the underlying layers in the direction of etching during the subsequent etch processing, is deposited over the anti-reflective coating material layer 132. The thickness of the photo resist 134 may preferably be in the range of about 60 nanometers to about 100 nanometers. The layer of photo resist 134 also defines the openings through which the etch process proceeds and may include a conventional positive photo resist material, such as, for example, organic photo resist materials, non-organic materials or combinations thereof.

As depicted in FIG. 4, the patterning of the lithographic stack 128 may then proceed to etch through the multilayer structure of FIG. 2, by selectively patterning to remove a portion of photo resist layer 134 over, for example, source region 114 and drain region 116. By way of example, this patterning process may be performed by employing a mask (not shown). In one example, a mask may be used to expose select portions of photoresist layer 134 with an exposure source from, for instance, a conventional stepper lithography system, resulting in the polymerization of the exposed photo resist layer. The portion of the exposed photo resist layer may then be developed using conventional wet chemistry, to remove the exposed or polymerized portions and to create a pattern that includes patterned openings 136, e.g. patterned openings 138 and 140 within photo resist layer 134, over source region 114 and drain region 116.

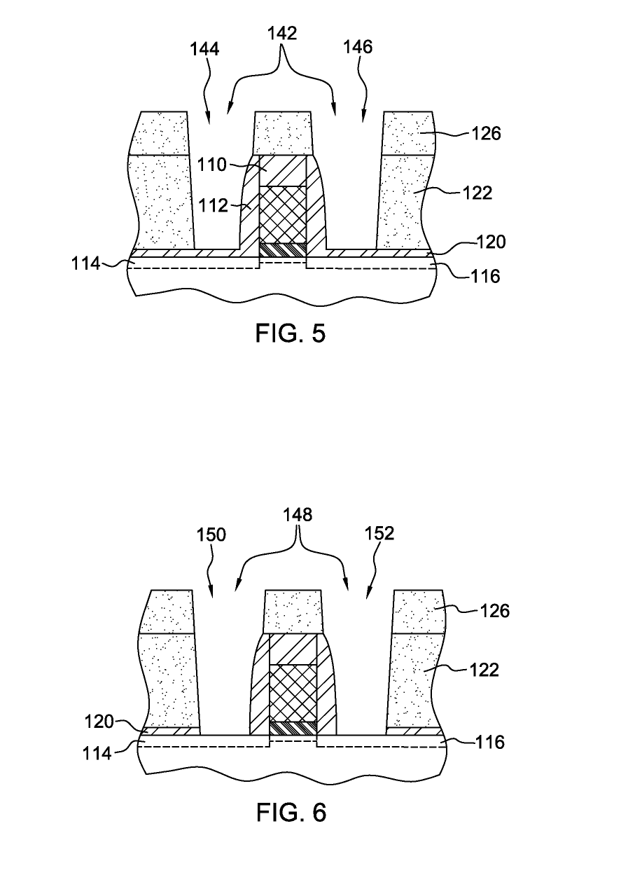

The patterned openings 136 in the photo resist layer of FIG. 4 may then be used to transfer the pattern to underlying dielectric layer 122 by extending downward through the underlying anti-reflective coating material layer 132 and organic planarizing layer 130. The transfer of the pattern further proceeds to selectively etch through additional dielectric layer 126 and dielectric filler layer/material 122, the selectivity being with respect to etch-resistant materials of the cap layer 110 and spacers 112, and stopping at first layer of protective material 120 without completely etching that layer, thereby creating intermediate contact openings 142 as shown in FIG. 5, e.g., intermediate contact openings 144 and 146, that extend through dielectric layer 122 but not through protective layer 120. Note that this transfer may be performed as one or more process steps such as, for example, an anti-reflective coating open step and an organic planarizing layer open step, followed by an etching process, which may be achieved by a conventional plasma etching process. In one example, if the dielectric layer 122 were to include an oxide material and first layer of protective material 120 were to include a nitride material, a CₓF_{y}-based chemistry may be employed along with additional process gases such as, for example, carbon monoxide (CO), oxygen (O₂) and argon (Ar), to selectively etch through dielectric layer 122 and to stop at first layer of protective material 120. Although shown for clarity in FIGS. 5-8 as if the source and drain contact regions 148 and gate structure 104 were co-planar, in practice preferably in a gate-first process sequence using an appropriate lithographic mask, the gate structure could be located in a forward or rearward plane with respect to the source and drain contacts. One example of this is shown in FIG. 1.

As further depicted in FIG. 5, any remaining material of lithographic stack 128 (see FIG. 4) is also removed in this process sequence. It should be noted that not all source and drain contacts need be created with a single lithographic sequence. In some process circumstances, it may be preferable to employ multiple lithographic process sequences followed be a combined etch process sequence, or multiple lithographic sequences and multiple etch sequences. In some distinct process circumstances where salicide would not be created for some source or drain regions, using appropriate lithographic masks, a similar dividing up of the lithographic and/or etching sequences can be employed. For clarity of the figures and understanding of the process description, these alternative sequences are included by reference, but not depicted.

Referring to FIG. 6, first layer of protective material 120 is selectively removed from within the source and drain intermediate contact openings 144 and 146 (see FIG. 5), thus extending the source and drain openings (generally, creating extended openings 148) to openings 150 and 152 reaching down to the various source and drains, which openings will subsequently contain one or more conductive contacts (also referred to simply as “contacts”) over the source region and drain region. Any suitable conventional etching process such as, for example, isotropic or anisotropic dry etching processes may be performed to remove first layer of protective material 120. In a specific example, anisotropic dry etching processes may include processes, such as, for example, reactive ion etching or plasma etching involving process gases, such as nitrogen trifluoride (NF₃) and hydrogen (H₂). In another example, if first layer of protective material 120 were to include, for instance, hafnium oxide (HfO₂), a boron trichloride (BCl₃) based dry etch chemistry may be employed to selectively etch the first layer of protective material. By way of example only, this selectivity in the etching processes advantageously facilitates in creating silicide selectively within the exposed source and drain.

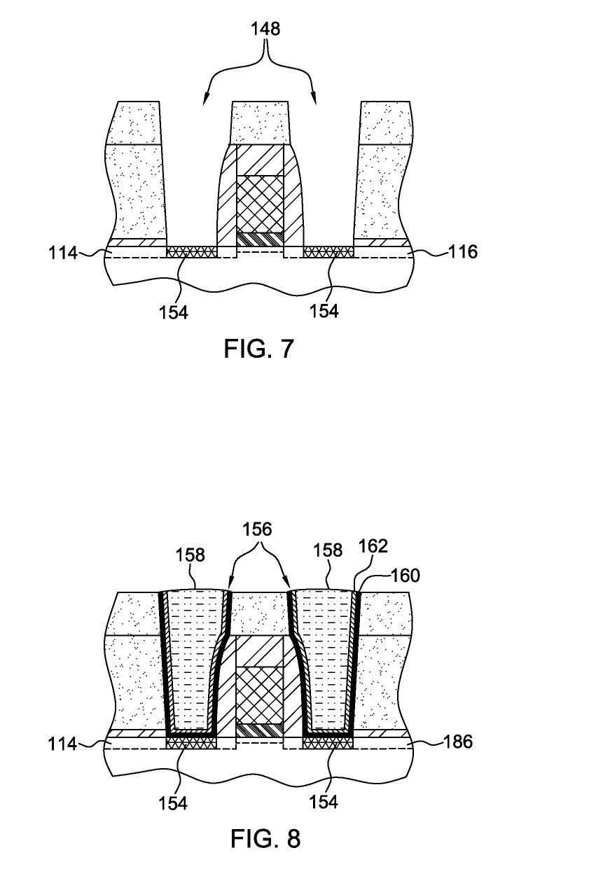

As shown in FIG. 7, salicide 154 (also referred to as “self-aligned silicide”) is formed in the source region 114 and drain region 116. One skilled in the art will understand that the salicide 154 (also referred to herein as “late silicide”) may be created after creating the extended openings 148 discussed above with respect to FIG. 6, as compared to a conventional early silicide process, wherein the silicidation process is performed before creating first layer of protective material 120 and dielectric filler material 122. This late silicidation process facilitates in preventing exposure of the created silicide to any subsequent ashing processes that may cause damage to silicide, and thereby improve the performance of the semiconductor device. Salicide 154 may be formed from a refractory metal, such as, for example, cobalt, nickel, titanium, tantalum, platinum, palladium, rhodium and mixtures thereof that have been chemically reacted with silicon, e.g., the silicon of source region 114 and drain region 116, exposed from within source and drain openings 148. In a specific example, nickel or a nickel-containing alloy may be deposited within the source and drain openings to allow contact with the silicon surface of the underlying source region 114 and drain region 116, and annealed at a temperature of about 450° C., for a time period sufficient to cause the nickel alloy layer to react with the underlying silicon, to form nickel salicide or a nickel alloy salicide using, for example, a rapid thermal anneal (RTP) process. In one example, the nickel salicide or nickel alloy salicide may include at least one of NiPtSiₓ, NiSiₓ, NiSiₓGe_{y}, and NiPtSiₓGe_{y} where 0≦x≦1 and 0≦y≦1. As one skilled in the art will understand, unreacted nickel or nickel-containing alloy may be removed from other regions of the structures on the semiconductor wafer by performing a selective etching process. This etching process is highly selective to remove the unreacted metal while not attacking the reacted salicide areas.

Referring to FIG. 8, the semiconductor processing proceeds with a contact metallization process to create electrical contacts within source and drain openings 148, electrically connecting to the source and drain regions of the transistors. Process steps to create the electrical contacts include conformally depositing contact liners 156 and providing conductive contact material 158 filling the lined openings. Note that conformally depositing contact liners 156 may include conformally depositing, for example, a gettering layer 160 within source and drain openings 148 and conformally depositing one or more barrier/adhesive layers 162 over gettering layer 160. Note that these layers may be formed using a variety of different materials and techniques, such as, for example, atomic layer deposition (ALD) and chemical vapor deposition (CVD). The thickness of the layers may also vary, depending upon the particular application. In one example, the conductive contact material 158 may include a bulk layer of tungsten within source and drain openings 148 (see FIG. 7) using a bottom-up growth process. A “bottom-up” process or “bottom-up fill” is used herein to describe the deposition or the formation of a metal within the opening and the continued process of depositing or forming metal from the bottom of the opening up to a desired stopping point, for example, the top of the opening.

In another example of the process, a tungsten nucleation layer (not shown) may be deposited over the adhesive/barrier layer 162 to facilitate the subsequent formation of the bulk tungsten material, using conventional deposition processes, such as chemical vapor deposition (CVD), atomic layer deposition (ALD) or pulsed nucleation layer deposition (PNL) deposition processes. The thickness of the nucleation layer may be about 1 nm to about 4 nm and may be deposited by, for instance, performing alternating pulsing sequences of boron-containing reducing agent and tungsten-containing precursor in presence of a reducing agent. The boron-containing reducing agents include, but are not limited to, borane (BH₃), diborane (B₂H₆), triborane, boron halides, such as, for example, boron trifluoride (BF₃), boron trichloride (BCl₃) and the like. The tungsten-containing precursors may include tungsten-containing gases, such as, for example, WF₆, WCl₆ and W(CO)₆ and the like, while the reducing agents may include hydrogen gas (H₂), silane (SiH₄), disilane (Si₂H₆), hydrazine (N₂H₄) and germane (GeH₄). In a specific example, the bulk deposition process involves a chemical vapor deposition (CVD) reaction of tungsten-containing precursor, such as tungsten hexafluoride (WF₆), and reducing gases, such as hydrogen (H₂) to produce tungsten and a by-product, such as, for example, hydrogen hexafluoride (HF) at temperature of about 250° C. to about 400° C.

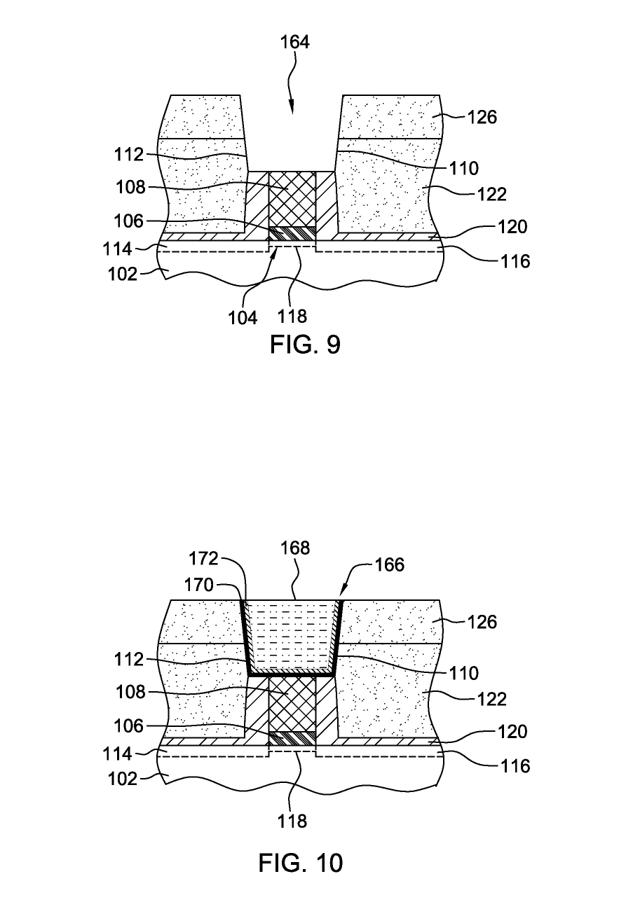

FIG. 9 is a cross-sectional view of one example of the semiconductor structure of FIG. 1, taken along cross-section 113, after one or more processes are performed to create gate opening 164 over gate structure 104, for instance, in a gate-last process sequence, an opening to dummy gate material 108, or in a gate-first process sequence, an opening to the gate metal layer, to facilitate the formation of conductive contacts or contact metallization to electrically connect to gate structure 104 of the transistor, without affecting the adjacent electrical contacts created within source and drain openings 148 (see FIG. 7). In one example, the one or more processes include etching through additional dielectric layer 126 and cap layer 110 disposed over dummy gate material 108 to create gate opening 164. Any suitable etching process, such as, for example, anisotropic dry etching processing, for example, reactive ion etching, may be employed to selectively remove the various layers to define gate opening 164. Subsequently, a conventional ashing process may be performed to remove all patterning materials, such as, for example, organic planarizing layers and photo resist.

Referring to FIG. 10, a contact metallization process is performed to create electrical contacts within gate opening 164 (see FIG. 9), to electrically connect to gate structure 104 of the transistor. As discussed above in connection with FIG. 8, process steps to create the electrical contacts include conformally depositing one or more contact liners 166 and providing conductive contact material 168 over contact liners 166. Conformally depositing contact liners 166 includes, for example, conformally depositing a gettering layer 170 within gate opening 164 (see FIG. 9) and conformally depositing one or more barrier/adhesive layers 172 over gettering layer 170. Note that these layers may be formed using a variety of different materials and techniques, such as, for example, atomic layer deposition (ALD) and chemical vapor deposition (CVD). The thickness of the layers may also vary, depending upon the particular application. In one example, a bulk layer of tungsten may be provided within gate openings 164 (see FIG. 9) as the conductive contact material, using a bottom-up growth process.

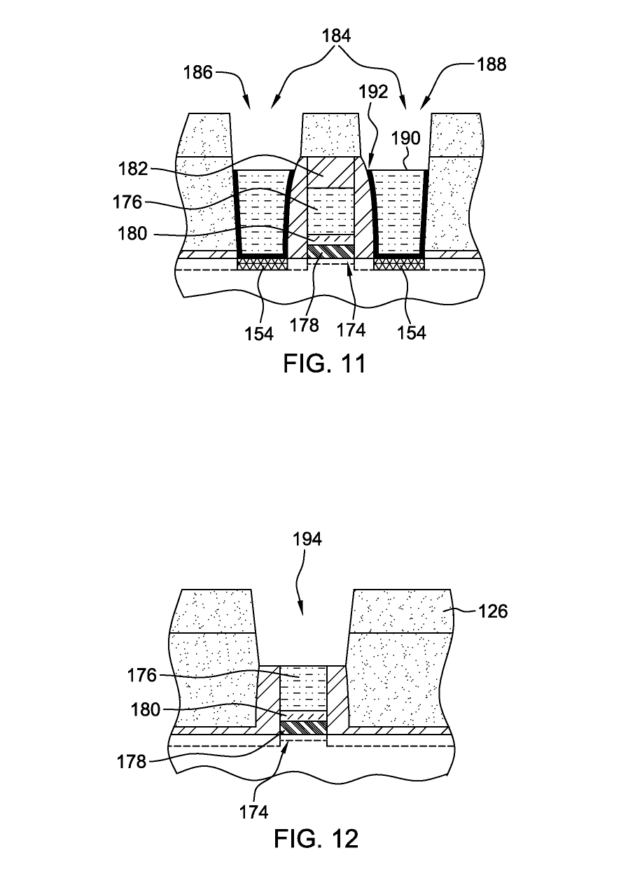

Alternatively, as depicted in FIGS. 11-14, the gate structure includes a metal gate material (versus a dummy gate material), for example, tungsten, common partial filling of the transistor source, drain and gate openings may be performed. Note that the FIG. 11 represents one example of a cross-sectional view of semiconductor structure 100, taken along the cross-section 111 (see FIG. 1). Accordingly, in a specific example, gate structure 174 may also include a metal gate material 176, such as, for example, tungsten, along with underlying one or more conformally deposited layers, such as gate dielectric layer 178 and one or more work function layers 180 deposited over gate dielectric layer 178. Note that a cap layer 182 which acts as a hard mask, is disposed over gate material 176. As discussed above and understood in the art, cap layer 182 is deposited to prevent short-circuiting, otherwise known as contact-to-gate (CTG) shorts, when the gate material comes into contact with the contact material, during subsequent fabrication. Cap layer 182 may include an insulator material such as, for example, silicon nitride, and may be deposited using any conventional deposition processes such as, for example, CVD, PVD and the like.

In this gate first example, the contact metallization may be performed to create electrical contacts within source and drain openings 184, to form partial source and drain contacts 186 and 188, using, for example, process conditions as described in connection with FIG. 8. The source contact and drain contact may be partially recessed by employing one or more controlled etching processes, as shown in FIG. 11, to selectively remove a portion of conductive contact material and underlying contact liners. In a specific example, the etching processes may include process gases involving activated fluorine species at a predetermined temperature to partially etch conductive contact material 190 and underlying contact liners 192. In one example, the activated fluorine species may be generated from NF₃/Ar or NF₃/He plasma in a remote plasma source or using other approaches. The height of the portion of conductive contact material 190 and contact liners 192 remaining in the source contact 186 and drain contact 188 may be in the range of about 10 nanometers to about 40 nanometers above the silicide

By way of an example, partial source and drain contacts 186 and 188 may alternatively be achieved by providing a contact liner 192 and conductive contact material 190, followed by partially recessing the contact liner and the conductive contact material. In a specific example, contact liner 192, such as titanium nitride (TiN), may be provided using conventional deposition processes, such as atomic layer deposition (ALD) or metal organic chemical vapor deposition (MOCVD) process followed by conductive contact material 190, such as tungsten (W). A two-step plasma-etch process may be employed to partially recess the contact liner and the conductive contact material, the two-step process being: (1) recessing conductive contact material 190 (for example, tungsten) selective to the contact liner material (e.g., TiN) using NF₃/Ar based plasma at a low pedestal temperature, for example, under 75° C., and then (2) recessing the contact liner (for example, titanium nitride) selective to the conductive contact material (e.g., tungsten,) at a higher temperature (for example, above 200° C.).

Next, one or more processes are performed to create gate opening 194 over gate structure 174, so as to facilitate the formation of a conductive contact or contact metallization to electrically connect to gate structure 174 of the transistor, as depicted in FIG. 12. In one example, one or more processes include etching through additional dielectric layer 126 and cap layer 182 to create gate opening 194. Any suitable etching processes, for example, anisotropic dry etching processing and/or reactive ion etching, may be employed to selectively remove the various layers to define gate opening 194. Note that the FIG. 12 represents one example of a cross-sectional view of semiconductor structure 100, taken along the cross-section 113 (see FIG. 1). Note that the silicide 154 of FIG. 11 remains unaffected during any subsequent gate patterning and/or ashing processes, due to the silicide being protected by the partially etched conductive contact material 190.

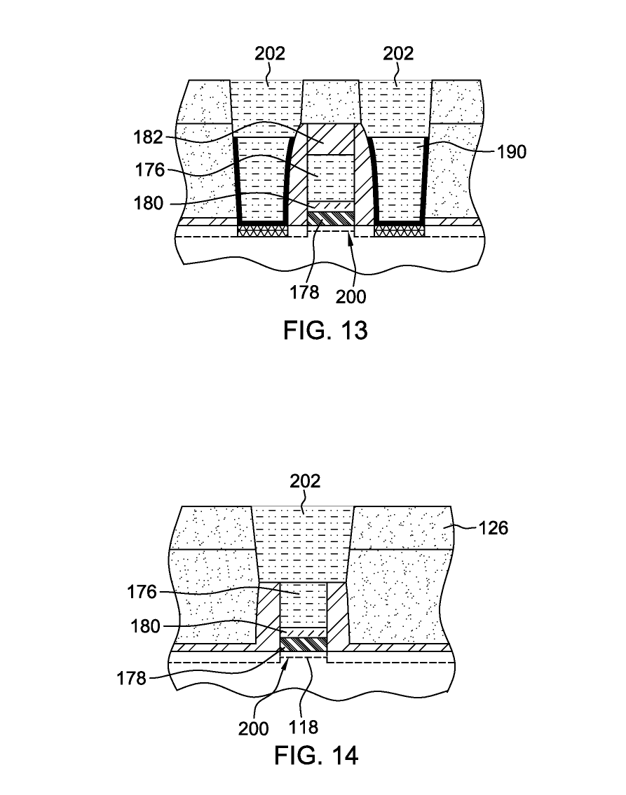

Referring to FIGS. 13 and 14, the contact metallization process continues to create a gate contact 202 within gate opening 194 (see FIG. 12) and complete the filling of the partially recessed source and drain contacts 202 (see FIG. 11). In a specific example, FIG. 13 represents one example of a cross-sectional view of semiconductor structure 100, taken along the cross-section 111 (see FIG. 1), while FIG. 14 represents one example of a cross-sectional view of semiconductor structure 100, taken along the cross-section 113 (FIG. 1). Note that contact liners conventionally provided within gate opening 194 may not be required during the formation of electrical contacts over gate structure 200, in the case of at least the top portion of the metal gate material being tungsten. In one example, the conductive contact material 202 may be conformally deposited using a conventional bottom-up growth process, as described previously. In one specific example, the bottom-up growth may be performed by selectively growing tungsten on the etched tungsten, which provides nucleation sites to grow large grain tungsten. This bottom-up growth process advantageously increases the volume of low resistance material, for instance, tungsten material, and refrains from the use of high resistive contact liners from the sidewalls of the contact structures, thereby reducing the contact resistance. Note that these layers may be formed using a variety of different materials and techniques, such as, for example, atomic layer deposition (ALD) and chemical vapor deposition (CVD). The thickness of the layers may also vary, depending upon the particular application.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A method, comprising:
providing a semiconductor structure for a transistor, the structure comprising: a semiconductor substrate; a source region, a drain region and a channel region therebetween; a layer of protective material above the source region and the drain region; a gate coupled to the channel region and having a cap and spacers, the cap and spacers comprising a protective material; and a layer of dielectric material enclosing the cap, spacers and protective layer above the source and drain regions;
etching openings to the gate cap and the protective layer over the source and drain regions;
etching through the protective layer to expose the source and drain regions without etching through the gate cap;
creating silicide in the source region and the drain region;
creating contacts in the source and drain openings;
extending the gate opening through the gate cap to expose the gate; and
creating a contact in the gate opening.

2. The method of claim 1, wherein creating a source, drain or gate contact comprises:
lining inner walls of the opening with a liner material; and
filling the lined opening with a contact material.

3. The method of claim 2, further comprising removing excess contact material.

4. The method of claim 2, wherein the contact material comprises tungsten, and wherein the filling comprises bottom-up growth of the tungsten.

5. The method of claim 1, wherein the protective material over the source and drain regions and that of the gate cap and spacers comprises a nitride, wherein the dielectric material comprises an oxide, wherein the silicide comprises nickel silicide, wherein the liner material comprises titanium nitride, and wherein the contact material comprises tungsten.

6. The method of claim 1, wherein the gate comprises at least a top portion of tungsten, and wherein creating the source and drain contacts comprises:
partially lining inner surfaces of the source and drain openings with a liner material; and
filling only the lined portions of the source and drain openings with tungsten.

7. The method of claim 6, wherein creating the source and drain contacts and creating the gate contact comprises performing a common bottom-up growth of tungsten on top of the tungsten in the gate, source and drain.

8. The method of claim 7, further comprising removing excess tungsten.

9. The method of claim 7, wherein the protective material over the source and drain regions and that of the gate cap and spacers comprises a nitride, wherein the dielectric material comprises an oxide, wherein the silicide comprises nickel silicide, wherein the liner material comprises titanium nitride, and wherein the contact material comprises tungsten.

10. A transistor, comprising:
a semiconductor substrate;
a source region, a drain region and a channel region therebetween;
a metal gate coupled to the channel region, at least a top conductive portion of the metal gate comprising tungsten;
an opening through at least one layer of one or more materials to each of the source region, drain region and gate;
a gate contact comprising tungsten filling the gate opening, wherein the gate contact is in direct contact with the top conductive portion of the gate;
silicide for the source and drain regions;
a liner lining inner surfaces of the source and drain openings part way up inner walls thereof; and
self-aligned tungsten contacts filling the source and drain openings.

11. The transistor of claim 10, wherein the at least one layer of one or more materials comprises at least one layer of a dielectric material.

12. The transistor of claim 11, wherein the dielectric material comprises an oxide.

13. The transistor of claim 10, wherein the at least one layer of one or more materials comprises at least one layer of a protective material.

14. The transistor of claim 13, wherein the protective material comprises a nitride.

15. The transistor of claim 10, wherein the silicide comprises one of NiPtSiₓ, NiSiₓ, NiSiₓGe_{y} and NiPtSiₓGe_{y}, wherein 0≦x≦1 and 0≦y≦1.

16. The transistor of claim 10, wherein the liner comprises one of titanium, titanium nitride, tantalum nitride and ruthenium.

17. The transistor of claim 10, wherein the transistor comprises a FinFET, having at least one fin coupled to the substrate, the at least one fin comprising the source region, drain region and channel region at a top portion thereof, and wherein the metal gate encloses the channel region.

18. A semiconductor structure, comprising:
a semiconductor substrate;
a source region, a drain region and a channel region therebetween;
a layer of protective material above the source region and the drain region;
a gate coupled to the channel region and having a cap and spacers, the cap and spacers comprising a protective material;
a layer of dielectric material enclosing the cap and source and drain regions; and
wherein the structure includes intermediate openings down to the gate cap and the protective layer over the source and drain regions.

19. The semiconductor structure of claim 18, wherein the openings over the source region and the drain region extend through the protective layer to the source and drain regions, the semiconductor structure further comprising silicide for the source and drain regions.

20. The semiconductor structure of claim 19, further comprising contacts in the openings to the source region and the drain region.
